(19) United States
(12) Patent Application Publication
(10) Pub. No.: US 2022/0069141 A1
(43) Pub. Date: Mar. 3, 2022

(54) LOW TEMPERATURE METALLIC INTERCONNECT FOR SOLAR CELL SHINGLING

(71) Applicant: Utica Leaseco, LLC, Rochester Hills, MI (US)

(72) Inventor: Todd Allen KRAJEWSKI, Mountain View, CA (US)

(21) Appl. No.: 17/459,032

(22) Filed: Aug. 27, 2021

Related U.S. Application Data
(60) Provisional application No. 63/071,837, filed on Aug. 28, 2020.

(51) Int. Cl. H01L 31/02; H01L 31/0392; H01L 31/18

(52) U.S. Cl. CPC H01L 31/0201; H01L 31/028; H01L 31/18; H01L 31/03926

(57) ABSTRACT

The present disclosure relates to electrical connections between shingled solar cells in a solar cell assembly. More particularly, the present disclosure describes the use of low temperature metallic interconnects that reduce resistivity between solar cells and assembly time. In an aspect, an assembly of shingled solar cells is described that includes a first solar cell having an insulating film on a back side, the insulating film having vias that expose a back metal layer of the first solar cell, and a second solar cell having a bus bar on a front side. In this assembly, the back metal layer of the first solar cell is electrically connected to the bus bar of the second solar cell through multiple electrical connections formed by low temperature solder that fills the vias in the insulating film of the first solar cell. A method of fabricating or manufacturing the assembly is also described.

### CROSS REFERENCE TO RELATED APPLICATIONS

This application claims priority to U.S. Patent Provisional Application No. 63/071,837, filed Aug. 28, 2020, the entire contents of which are hereby incorporated by reference in their entirety.

### BACKGROUND

The present disclosure relates generally to the types of electrical connections used between solar cells in a solar cell assembly or module in which the solar cells are shingled, and more specifically, to the use of low temperature metallic interconnects to improve performance and assembly time.

In some solar cell assemblies or modules, the solar cells are arranged such that, in general, a far end of a solar cell overlaps a near end of another solar cell. This arrangement may provide for higher packing densities of solar cells, thereby increasing the active area of the assembly or module. Adhesives are generally used in the overlapping area to provide some form of mechanical strength between the overlapping solar cells. Moreover, electrical connections between the overlapping solar cells are generally made by using electrically conductive epoxies or adhesives (ECA). Since many types of solar cells are rigid, the use of ECA provides some flexibility or give at the electrical connections (e.g., the electrical joints) between the solar cells.

Current electrically conductive epoxies require a significant amount of time at or above a recommended cure temperatures to develop the designed properties. For example, the typical amount of time is between 5 to 15 minutes at a cure temperature greater than 135° C., and sometimes the amount of cure time can be as much as 30 minutes. Current electrically conductive epoxies also have a higher resistivity when compared to that of metals. For example, for electrically conductive epoxies the resistivity can be about 1×10⁻⁴ ohm-cm, while the resistivity for metals can be about 1×10⁻⁷ ohm-cm). When compared to metals, electrically conductive epoxies also have limitations regarding handling, pot life, and storage.

It is therefore desirable to have techniques for making electrical connections between shingled solar cells that improve the fabrication or assembly time and that improve upon the physical characteristics of the electrical connections, including the resistivity of the electrical connections.

### SUMMARY OF THE DISCLOSURE

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description that is subsequently presented.

In an aspect of this disclosure, a solar cell assembly with shingled solar cells is described that includes a first solar cell having an insulating film on a back side, the insulating film having vias that expose a back metal layer of the first solar cell, and a second solar cell having a bus bar on a front side. The back metal layer of the first solar cell is electrically connected to the bus bar of the second solar cell through multiple electrical connections formed by low temperature solder that fills the vias in the insulating film of the first solar cell.

In another aspect of this disclosure, a method of fabricating a solar cell assembly with shingled solar cells is described that includes providing a first solar cell having an insulating film on a back side, the insulating film having vias that expose a back metal layer of the first solar cell; providing a second solar cell having a bus bar on a front side; disposing a low temperature solder in each of the vias, the low temperature solder forming a solder bump in each via that protrudes slightly over a back surface of the insulating film; positioning the front side of the second solar cell over the back side of the first solar cell with the bus bar of the second solar cell overlapping and contacting a top part of the solder bumps in the vias of the first solar cell; and pressing the first solar cell together with the second solar cell and applying heat to reflow the solder bumps to form multiple electrical connections between the back metal layer of the first solar cell and the bus bar of the second solar cell.

### BRIEF DESCRIPTION OF THE DRAWINGS

The appended drawings describe only some implementations for illustrative purposes and are therefore not to be considered limiting of scope. It is to be understood that some of the sizes and/or thicknesses (or relative sizes and/or thicknesses) of different elements presented in the drawings need not be representative of actual or likely sizes and/or thickness and are merely used to more clearly illustrate various concepts of this disclosure.

FIG. 1 illustrates an example of an assembly of shingled solar cells in accordance with aspects of this disclosure.

FIG. 2 illustrates an example of vias in an insulating film on the back of a solar cell having low temperature solder bumps in accordance with aspects of this disclosure.

FIG. 3 illustrates an example of joining two solar cells by forming electrical connections with the low temperature solder bumps in accordance with aspects of this disclosure.

FIG. 4 illustrates an example of a method of fabricating a solar cell assembly using low temperature solder bumps in accordance with aspects of this disclosure.

### DETAILED DESCRIPTION

The present disclosure relates generally to the types of electrical connections used between solar cells in a solar cell assembly or module in which the solar cells are shingled, and more specifically, to the use of low temperature metallic interconnects to improve performance and assembly time.

As described above, current electrically conductive epoxies or adhesives require a significant amount of time at or above a recommended cure temperature to develop the designed properties. Moreover, they tend to have a higher resistivity when compared to the resistivity of metals. The present disclosure describes the use of a low temperature solder as a replacement for electrically conductive epoxies or adhesives used in stringing/shingling of solar cells. The use of low temperature solder may improve overall assembly time and electrical resistivity. Although metallic electrical connections based on low temperature solder may be stiffer than those based on electrically conductive epoxies or adhesives, such an issue may be less of a concern when the solar cells in the assembly are flexible solar cells. In contrast to rigid solar cells where some flexibility at the electrical connections may be desirable, flexible solar cells already have sufficient flexibility or give and the electrical connections can be stiffer than for rigid solar cells.

The low temperature solder would preferably have a liquidus/solidus temperature that is less than 170° C. Liquidus refers to a temperature at which an alloy is completely melted. The solidus is the highest temperature at which an alloy is solid—where melting begins. In some instances, the low temperature solder is a eutectic system. A eutectic system is a homogeneous, solid mixture of two or more substances (e.g., an alloy or mixture of alloys) that either melts or solidifies at a lower temperature than the melting point of any of the individual substances. The low temperature solder may be typically made of alloys based on indium (In), bismuth (Bi), or tin/lead/silver (Sn/Pb/Ag).

TABLE 1
Different alloys for low temperature solder.

| Liquidus | Solidus | Element 1 | Element 2 | Element 3 |
|---|---|---|---|---|
| (° C.) | (° C.) | % | % | % |
| 118 | 118 | In 52.0 | Sn 48.0 | |
| 125 | 118 | Sn 50.0 | In 50.0 | |
| 131 | 118 | Sn 52.0 | In 48.0 | |
| 138 | 138 | Bi 58.0 | Sn 42.0 | |
| 140 | 139 | Bi 57.0 | Sn 42.0 | Ag 1.0 |
| 143 | 143 | In 97.0 | Ag 3.0 | |
| 145 | 118 | Sn 58.0 | In 42.0 | |
| 150 | 125 | In 95.0 | Bi 5.0 | |
| 150 | 150 | In 99.3 | Ga 0.7 | |
| 151 | 143 | In 90.0 | Sn 10.0 | |
| 152 | 152 | In 99.4 | Ga 0.6 | |
| 153 | 153 | In 99.6 | Ga 0.4 | |
| 154 | 149 | In 80.0 | Pb 15.0 | Ag 5.0 |
| 154 | 154 | In 99.5 | Ga 0.5 | |
| 157 | 157 | In 100.0 | | |
| 175 | 165 | In 70.0 | Pb 30.00 | |

Table 1 above shows some examples of low temperature solders. In some instances, the low temperature solder may have a small split or no split between the liquidus and the solidus temperatures. Examples include Bi/Sn alloy at a ratio of 58/42 with the same liquidus and solidus temperature of 138° C., In/Ag allow at a ratio of 97/3 with the same liquidus and solidus temperature of 143° C., or Bi/Sn/Ag alloy at a ratio of 57/42/1 with liquidus temperature of 140° C. and solidus temperature of 139° C. In other instances, the low temperature solder may have a large split between the liquidus and the solidus temperatures

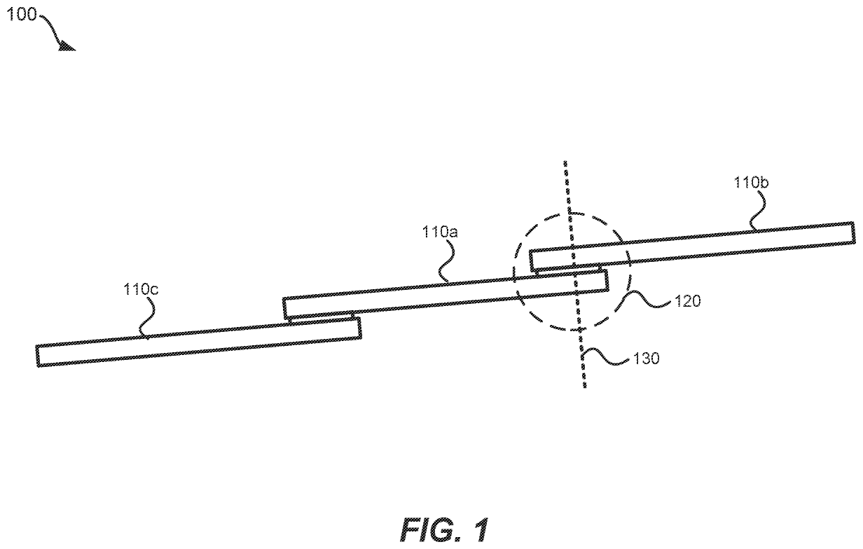

In this disclosure, back contact vias in a solar cell are to be filled with low temperature solder. For example, back contact vias in a solar cell may be filled using a molten solder jetting process or a solder ball placement/reflow technique resulting in a solder bump that is slightly proud (e.g., extends or protrudes) from an insulating surface. A bus bar in the next solar cell in the assembly is aligned with these solder bumps and a simple heat stake setup is used to press the solar cells together, thereby heating/reflowing the solder bumps and joining the solar cells. As the thermal mass of the solar cells and the solder is very small, the heating/cooling cycle is rapid and takes the cure time issue out of the process. Additional details regarding the proposed approach are described below in connection with FIGS. 1-4.

FIG. 1 shows a diagram 100 that illustrates an example of an assembly or module having shingled solar cells in accordance with aspects of this disclosure. The diagram 100 shows a side view of multiple, shingled solar cells, including solar cells 110a, 110b, and 110c. Although three (3) solar cells are shown, it is to be understood that the assembly or module can include more than three solar cells and that additional sets of solar cells can be included to either or both sides of those in the diagram 100 (e.g., additional solar cells could be added into the plane in the diagram 100 and/or out of the plane of the diagram 100).

The solar cell 110b overlaps the solar cell 110a in an overlapping region 120. A similar overlap occurs between the solar cell 110a and the solar cell 110b. A plane 130 shown in the overlapping region 120 corresponds to a plane in which electrical connections can be made between the solar cell 110b and the solar cell 110a. In the overlapping region 120, adhesives and/or adhesive films may be used to mechanically hold together the solar cells. The electrical connections that are formed between the solar cells as described in this disclosure may provide a rigid joint but are generally too small to be the primary mechanism for holding the solar cells together.

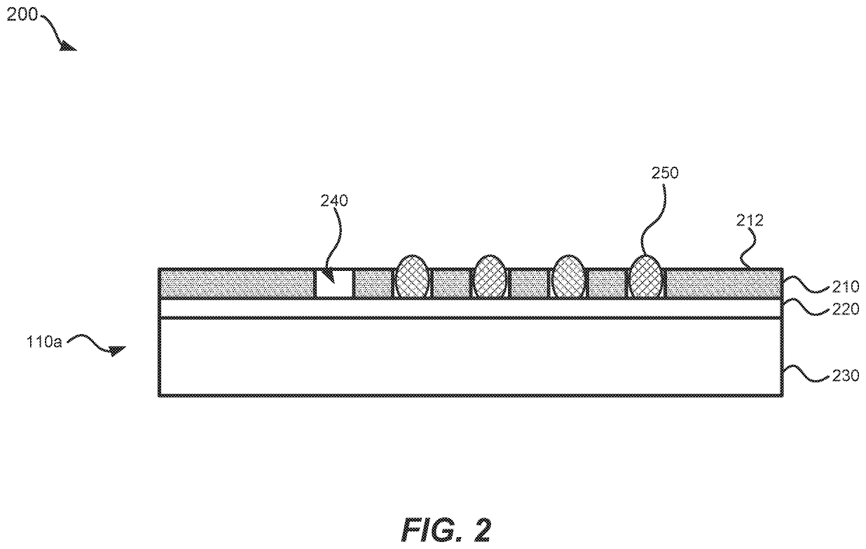

FIG. 2 shows a diagram 200 that illustrates an example of vias 240 (e.g., back contact vias) in an insulating film 210 on the back of the solar cell 110a with low temperature solder bumps 250 inside the vias 240. In this example, the solar cell 110a has the insulating film or carrier 210 on a back side (e.g., a side away from where light is to be incident on the solar cell 110a). The solar cell 110a also has a back metal layer or back metal 220, a surface of which is exposed at certain points by the vias 240 formed through the insulating film 210. The solar cell 110a also includes an active photovoltaic (PV) region 230 that absorbs light and converts it into electrical energy on a front side (e.g., a side where light is to be incident on the solar cell 110a). In some examples, the active PV region 230 can be made of multiple layers, including epitaxially grown layers, that include group III-V semiconductor materials or other types of semiconductor materials. The front side is sometimes referred to as the sun or sunny side of the solar cell 110a. The solar cell 110a as depicted in the diagram 200 is a simplified version of a solar cell for purposes of illustration. For example, although not shown, the solar cell 110a may also include a front metal or front metal layer and front metal electrodes, including electrode fingers and a bus bar.

As shown in the diagram 200, the low temperature solder bumps 250 may be formed in each of the vias 240 and may extend or protrude slightly over a back surface 212 of the insulating film 210. There may be different ways to form the solder bumps 250. One approach is to place a paste of the low temperature solder with a flux and process the paste to form the solder bumps 250. The paste may be deposited using, for example, a jetting or jet printing process or some other form of paste dispensing. Another approach may be to flux the metal at the bottom of the vias 240 (e.g., copper of the back metal 220) and put a ball of low temperature solder and use a laser to heat it and tack it in place (e.g., reflow it). There may be other approaches in which the low temperature solder may wet the back metal 220 exposed at the bottom of the vias 240 but consideration may need to be given to oxidation in the metal surface.

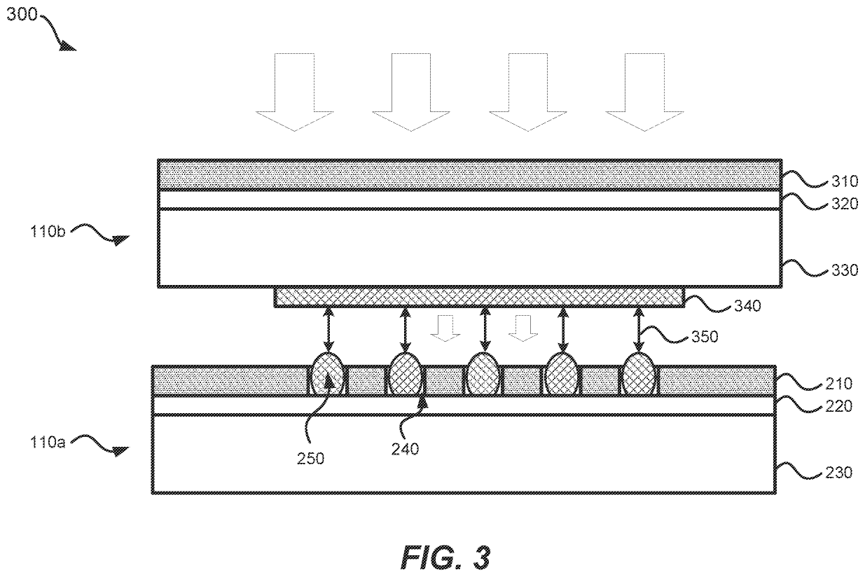

FIG. 3 shows a diagram 300 that illustrates an example of joining two solar cells (e.g., the solar cells 110a and 110b) by forming electrical connections with the low temperature solder bumps in accordance with aspects of this disclosure. A solar cell assembly or module like the one shown in the diagram 100 in FIG. 1 may include pairs of solar cells joined in the manner described in the diagram 300. In this example, the solar cell 110a is joined to the solar cell 110b. As described above, the solar cell 110a includes the insulating film 210, the back metal 220, and the active PV region 230, with solder bumps 250 in each of the vias 240. The solar cell 110b may include an insulating film 310, a back metal 320, an active PV region 330, and a bus bar 340 on a front side of the solar cell 110b. Although not shown in this example, if a back side of the solar cell 110b were to be joined to another solar cell, the insulating film 310 may also have vias with solder bumps in them.

As illustrated by the diagram 300, the bus bar 340 is pressed against the solder bumps 250 with heat and pressure being applied so as to form electrical connections 350 between the two solar cells. As mentioned above, the use of metals in the low temperature solder of the solder bumps 350 provides improved resistivity when compared to electrically conductive epoxies or adhesives. Moreover, the heating and pressure process to form the electrical connections 350 is significantly shorter than the 5 to 30 minutes that it can take to cure the electrically conductive epoxies or adhesives.

Based on the diagram 300, the present disclosure proposes a solar cell assembly or module for shingled solar cells that includes a first solar cell (e.g., the solar cell 110a) having an insulating film on a back side, where the insulating film has vias that expose a back metal layer of the first solar cell. The solar cell assembly or module also includes a second solar cell (e.g., the solar cell 110b) having a bus bar on a front side. The back metal layer of the first solar cell is electrically connected to the bus bar of the second solar cell through multiple electrical connections formed by low temperature solder that fills the vias in the insulating film of the first solar cell.

For the proposed solar cell assembly or module, the shingled solar cells, which include the first solar cell and the second solar cell, are flexible solar cells. The flexible solar cells used for the solar cell assembly or module include flexible solar cells made of group III-V semiconductor materials, thin-film silicon solar cells, or flexible cupper indium gallium selenide (CIGS) solar cells.

For the proposed solar cell assembly or module, the low temperature solder has a liquidus temperature and a solidus temperature that is less than 170° C. In some instances, the low temperature solder is a eutectic system. Moreover, the low temperature solder is a fusible metal alloy that includes one of an indium alloy, a bismuth alloy, or an alloy including tin, lead, and silver (see e.g., Table 1).

For the proposed solar cell assembly or module, the first solar cell and the second solar cell are mechanically held together by one or more adhesives, one or more adhesive films, or a combination thereof. The physical joints produced by the electrical connections are stiff joints but are not intended to be the primary mechanism to hold the solar cells together.

For the proposed solar cell assembly or module, a third solar cell (e.g., the solar cell 110c) may have an insulating film on a back side, the insulating film of the third solar cell having vias that expose a back metal layer of the third solar cell. In this case, the first solar may have a bus bar on a front side, and the back metal layer of the third solar cell is electrically connected to the bus bar of the first solar cell through multiple electrical connections formed by low temperature solder that fills the vias in the insulating film of the third solar cell.

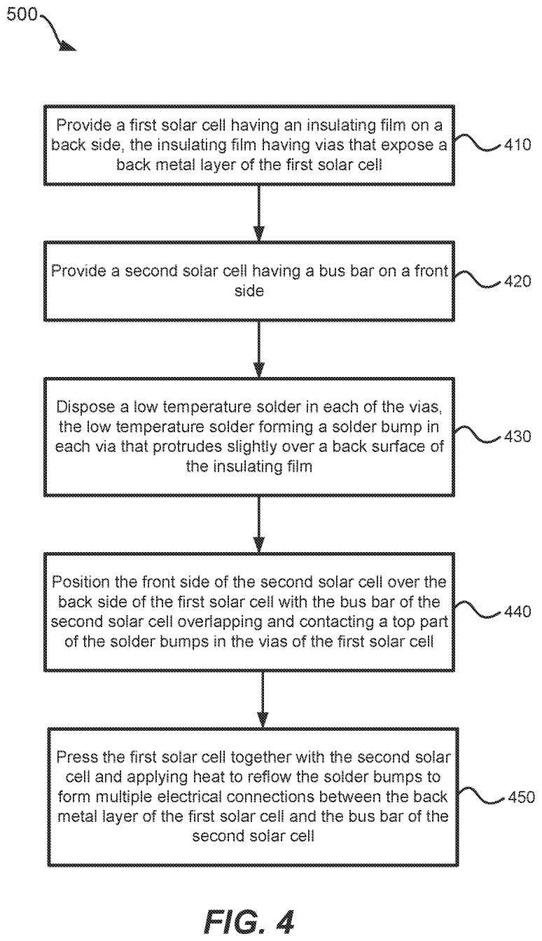

FIG. 4 illustrates an example of a method 400 of fabricating a solar cell assembly with shingled solar cells using low temperature solder bumps in accordance with aspects of this disclosure.

At 410, the method 400 includes providing a first solar cell (e.g., the solar cell 110a) having an insulating film (e.g., the insulating film 210) on a back side, the insulating film having vias (e.g., the vias 240) that expose a back metal layer (e.g., the back metal layer 220) of the first solar cell.

At 420, the method 400 includes providing a second solar cell (e.g., the solar cell 110b) having a bus bar (e.g., the bus bar 340) on a front side.

At 430, the method 400 includes disposing or placing a low temperature solder in each of the vias, where the low temperature solder forms a solder bump (e.g., the solder bump 250) in each via that protrudes slightly over a back surface of the insulating film (e.g., the back surface 212).

At 440, the method 400 includes positioning or arranging the front side of the second solar cell over the back side of the first solar cell with the bus bar of the second solar cell overlapping and contacting a top part of the solder bumps in the vias of the first solar cell. Alternatively, the first solar cell may be positioned or arranged over the second solar cell.

At 450, the method 400 includes pressing (e.g., applying pressure) the first solar cell together with the second solar cell and applying heat to reflow the solder bumps to form multiple electrical connections between the back metal layer of the first solar cell and the bus bar of the second solar cell. In some implementations, pressure may be applied to both solar cells or just to one of the solar cells.

In an aspect of the method 400, disposing the low temperature solder in each of the vias includes disposing a molten low temperature solder paste in each of the vias. Moreover, disposing the molten low temperature solder paste in each of the vias includes jet printing the molten low temperature solder paste into each of the vias.

In another aspect of the method 400, disposing the low temperature solder in each of the vias includes placing a low temperature solder ball in each of the vias and reflowing the low temperature solder ball. The method 400 may further include fluxing an exposed surface of the back metal layer of the first solar cell prior to placing the low temperature solder ball in each of the vias.

In another aspect of the method 400, applying heat may further include applying heat at a temperature that is less than 170° C. to reflow the low temperature solder in the solder bumps.

In another aspect of the method 400, the first solar cell and the second solar cell are flexible solar cells. The flexible solar cells may include flexible solar cells made of group III-V semiconductor materials, thin-film silicon solar cells, and flexible cupper indium gallium selenide (CIGS) solar cells.

In another aspect of the method 400, the low temperature solder is a eutectic system.

In another aspect of the method 400, the low temperature solder is a fusible metal alloy that includes one of an indium alloy, a bismuth alloy, or an alloy including tin, lead, and silver.

The description provided above is presented to enable one of ordinary skill in the art to make and use aspects of this disclosure and is provided in the context of a patent application and its requirements. Various modifications to implementations and the generic principles and features described herein will be readily apparent to those skilled in the art. Thus, the present disclosure is not intended to be limited to the implementations shown, but is to be accorded the widest scope consistent with the principles and features described herein.

What is claimed is:

1. A solar cell assembly with shingled solar cells, comprising:
a first solar cell having an insulating film on a back side, the insulating film having vias that expose a back metal layer of the first solar cell; and
a second solar cell having a bus bar on a front side,
wherein the back metal layer of the first solar cell is electrically connected to the bus bar of the second solar cell through multiple electrical connections formed by low temperature solder that fills the vias in the insulating film of the first solar cell.

2. The solar cell assembly of claim 1, wherein the shingled solar cells, including the first solar cell and the second solar cell, are flexible solar cells.

3. The solar cells assembly of claim 2, wherein the flexible solar cells include flexible solar cells made of group III-V semiconductor materials, thin-film silicon solar cells, or flexible cupper indium gallium selenide (CIGS) solar cells.

4. The solar cell assembly of claim 1, wherein the low temperature solder has a liquidus temperature and a solidus temperature that is less than 170° C.

5. The solar cell assembly of claim 1, wherein the low temperature solder is a eutectic system.

6. The solar cell assembly of claim 1, wherein the low temperature solder is a fusible metal alloy that includes one of an indium alloy, a bismuth alloy, or an alloy including tin, lead, and silver.

7. The solar cell assembly of claim 1, wherein the first solar cell and the second solar cell are mechanically held together by one or more adhesives, one or more adhesive films, or a combination thereof.

8. The solar cell assembly of claim 1, further comprising:
a third solar cell having an insulating film on a back side, the insulating film of the third solar cell having vias that expose a back metal layer of the third solar cell,
wherein the first solar has a bus bar on a front side, the back metal layer of the third solar cell being electrically connected to the bus bar of the first solar cell through multiple electrical connections formed by low temperature solder that fills the vias in the insulating film of the third solar cell.

9. A method of fabricating a solar cell assembly with shingled solar cells, comprising:
providing a first solar cell having an insulating film on a back side, the insulating film having vias that expose a back metal layer of the first solar cell;
providing a second solar cell having a bus bar on a front side;
disposing a low temperature solder in each of the vias, the low temperature solder forming a solder bump in each via that protrudes slightly over a back surface of the insulating film;
positioning the front side of the second solar cell over the back side of the first solar cell with the bus bar of the second solar cell overlapping and contacting a top part of the solder bumps in the vias of the first solar cell; and
pressing the first solar cell together with the second solar cell and applying heat to reflow the solder bumps to form multiple electrical connections between the back metal layer of the first solar cell and the bus bar of the second solar cell.

10. The method of claim 9, wherein disposing the low temperature solder in each of the vias includes disposing a molten low temperature solder paste in each of the vias.

11. The method of claim 10, wherein disposing the molten low temperature solder paste in each of the vias includes jet printing the molten low temperature solder paste into each of the vias.

12. The method of claim 9, wherein disposing the low temperature solder in each of the vias includes placing a low temperature solder ball in each of the vias and reflowing the low temperature solder ball.

13. The method of claim 12, further comprising fluxing an exposed surface of the back metal layer of the first solar cell prior to placing the low temperature solder ball in each of the vias.

14. The method of claim 9, wherein applying heat further includes applying heat at a temperature that is less than 170° C. to reflow the low temperature solder in the solder bumps.

17. The method of claim 9, wherein the first solar cell and the second solar cell are flexible solar cells.

18. The method of claim 17, wherein the flexible solar cells include flexible solar cells made of group III-V semiconductor materials, thin-film silicon solar cells, and flexible cupper indium gallium selenide (CIGS) solar cells.

19. The method of claim 9, wherein the low temperature solder is a eutectic system.

20. The method of claim 9, wherein the low temperature solder is a fusible metal alloy that includes one of an indium alloy, a bismuth alloy, or an alloy including tin, lead, and silver.
